(19) United States
(12) Patent Application Publication
(10) Pub. No.: US 2026/0119186 A1
(43) Pub. Date: Apr. 30, 2026

(54) METHOD AND SYSTEM FOR WARMING A CHIP DURING A BOOTING SEQUENCE USING EXISTING CIRCUITRY ON THE CHIP

(71) Applicant: NVIDIA Corporation, Santa Clara, CA (US)

(72) Inventors: Ge Yang, Pleasanton, CA (US); Tezaswi Raja, San Jose, CA (US)

(21) Appl. No.: 18/933,708

(22) Filed: Oct. 31, 2024

(51) Int. Cl. G06F 9/4401; G06F 11/30; H05K 7/20

(52) U.S. Cl. CPC G06F 9/4401; G06F 11/3058; H05K 7/20

(57) ABSTRACT

The disclosure provides a method, apparatus, and system for operating chips that satisfy operating at a minimum operating temperature but include circuitry that has not been validated to operate at the minimum operating temperature. In one example the disclosure provides a method of booting a chip that includes: (1) initiating a booting sequence for a chip in response to receiving a boot-up signal, (2) determining a chip temperature using a temperature sensor, (3) activating warming circuitry of the chip during the booting sequence when the chip temperature is less than a first temperature, wherein the warming circuity is configured to operate at a second temperature, and (4) when activated, deactivating the warming circuitry when the chip temperature is equal to or greater than the first temperature.

### TECHNICAL FIELD

This application is directed, in general, to chips, and more specifically, to operating chips at a low temperature.

### BACKGROUND

Computing devices are used in many aspects that range from communications to vehicles. Computing devices include one or more processors that perform operations on data stored in memory to perform desired functions. Typically the processors and memory include multiple integrated circuits (ICs), also known as chips, which are configured for the processing and/or storing of data.

The chips are manufactured to operate within certain temperature ranges. Sometimes this can be a problem when the computing devices are located in harsh environments. Considering vehicles as an example, the chips can be located in areas where the temperature can be extremely cold and/or extremely hot. As such, various industries have standards to ensure operation within particular temperatures. For example, the automotive industry has a standard requiring operation at −40 degrees Celsius.

### SUMMARY

In one aspect, the disclosure provides a method of booting a chip. In one example, the method includes: (1) initiating a booting sequence for a chip in response to receiving a boot-up signal, (2) determining a chip temperature, (3) activating warming circuitry of the chip during the booting sequence when the chip temperature is less than a first temperature, wherein the warming circuity is configured to operate at a second temperature, (4) when activated, deactivating the warming circuitry when the chip temperature is equal to or greater than the first temperature, and (5) activating one or more additional circuits of the chip when the chip temperature is equal to or greater than the first temperature, wherein the first temperature is greater than the second temperature.

In yet another aspect, the disclosure provides a boot controller for initiating a booting sequence of a chip. In one example, the boot controller includes: (1) an interface for receiving a boot-up signal, wherein the boot-up signal initiates the booting sequence, and (2) a warming controller to perform operations during the booting sequence that include: (a) sensing a chip temperature using one or more temperature sensor, (b) activating warming circuitry of the chip when the chip temperature is less than a first temperature, wherein the warming circuity is configured to operate at a second temperature, (c) checking the chip temperature when the warming circuitry is activated, and (d) deactivating the warming circuitry after activation when the chip temperature is at least the first temperature.

In still another aspect, the disclosure provides a method of configuring a boot loader for a chip. In one example the method includes: (1) determining an available amount of time for heating a chip from a first temperature to a second temperature during a booting sequence of the chip, (2) calculating a total amount of current required for heating the chip from the first temperature to the second temperature during the available amount of time, and (3) loading the booting sequence in the boot loader, wherein the booting sequence includes instructions for activating warming circuitry of the chip to attain the total amount of current in the available amount of time.

In still yet another aspect, the disclosure provides a computer program product having a series of operating instructions stored on a non-transitory computer readable medium that direct operation of one or more processors when initiated to perform a booting sequence for a chip, wherein the booting sequence includes: (1) activating warming circuitry of a chip when a temperature of the chip is less than a first temperature, wherein the warming circuity is configured to operate at a second temperature, (2) sensing the chip temperature during the booting sequence when the warming circuitry is activated, and (3) deactivating the warming circuitry after the sensing when the chip temperature is equal to or greater than the first temperature.

### BRIEF DESCRIPTION

Reference is now made to the following descriptions taken in conjunction with the accompanying drawings, in which:

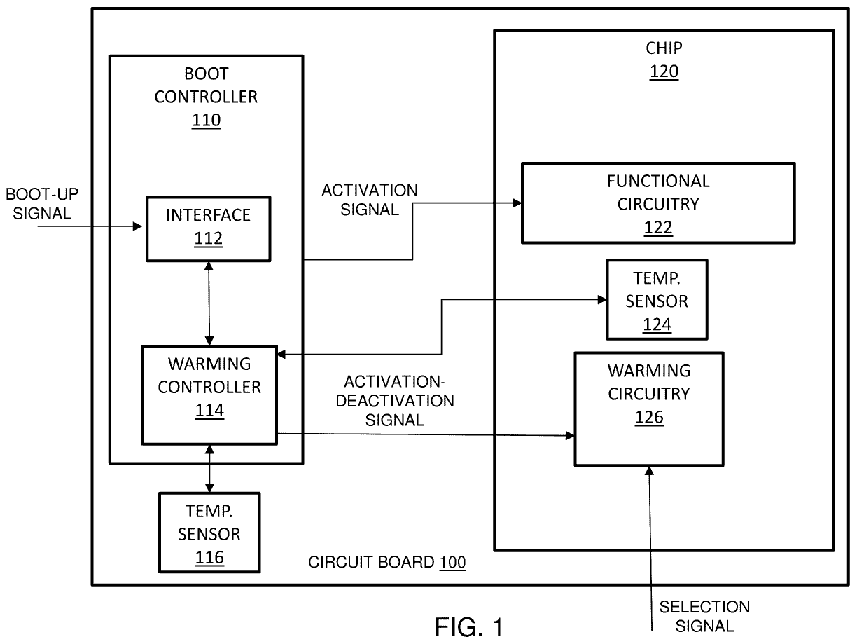

FIG. 1 illustrates a block diagram of an example of a circuit board including a boot controller constructed according to the principles of the disclosure;

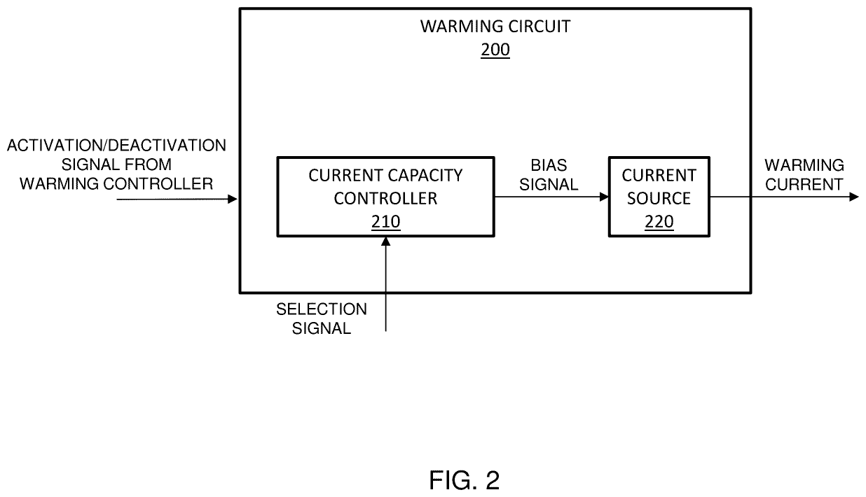

FIG. 2 illustrates a block diagram of an example of a warming circuit constructed according to the principles of the disclosure;

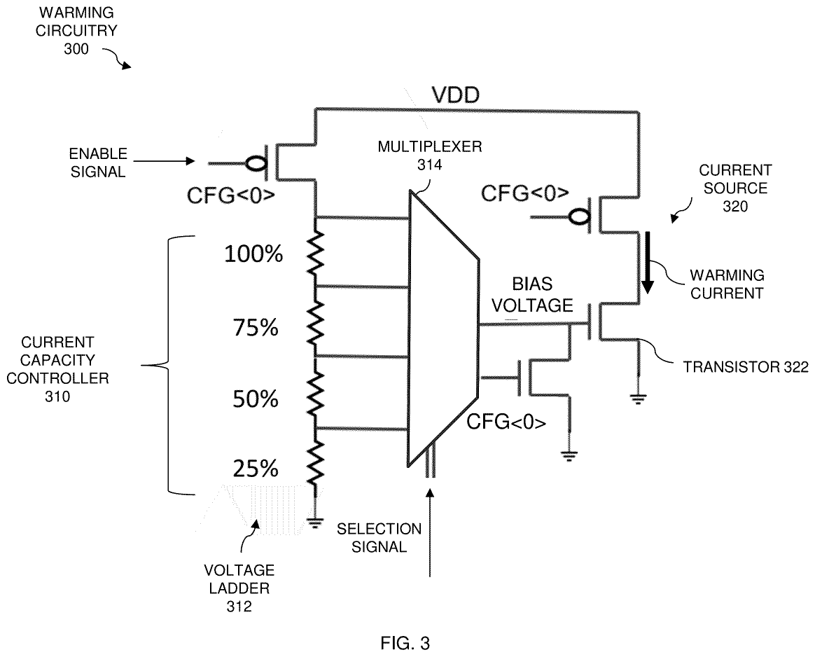

FIG. 3 illustrates a schematic diagram of an example of a warming circuit constructed according to the principles of the disclosure;

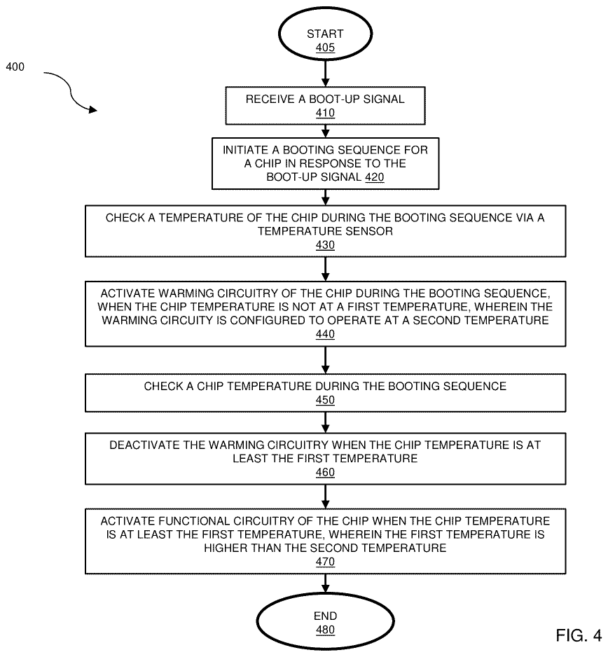

FIG. 4 illustrates a flow diagram of an example of a method of booting a chip carried out according to the principles of the disclosure; and

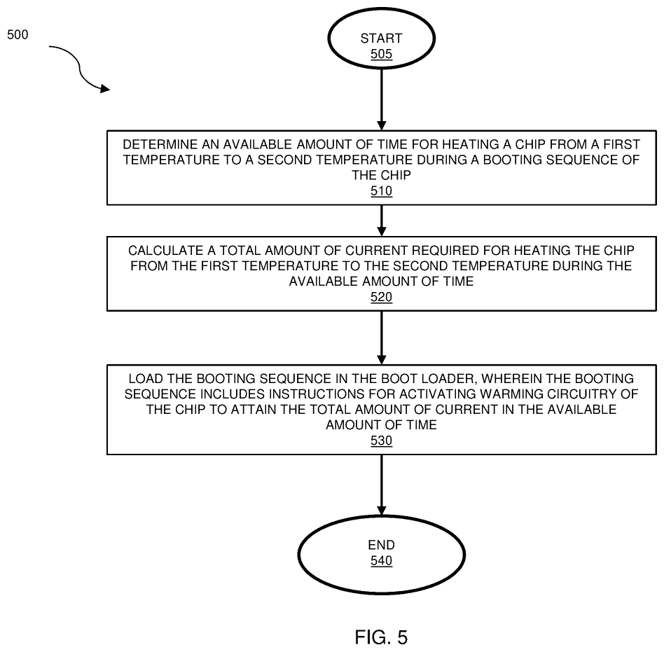

FIG. 5 illustrates a flow diagram of an example of a method of configuring a boot loader for a chip carried out according to the principles of the disclosure.

### DETAILED DESCRIPTION

Current that is flowing through a chip will heat the chip. However, before the chip is activated the current flowing through the chip is merely leakage current, which is typically insufficient to heat the chip to a minimum required temperature in certain environments. Once activated, the current through a chip is increased, which can be used to increase the temperature of the chip.

The disclosure provides a system and method for satisfying a minimum operating temperature (MOT) of a chip by activating warming circuitry of the chip at boot-up wherein the warming circuitry is configured to operate at the MOT. As such, the warming circuitry has been validated to function correctly for its intended purpose at the MOT. Activation of the warming circuitry can be based on a temperature of the chip at boot-up. One or more temperature sensors can be enabled to determine if a boot-up temperature of the chip is satisfied. If so, the warming circuitry does not need to be enabled during the boot-up process. If the boot-up temperature is not satisfied at boot-up, then the warming circuitry can be activated. The one or more temperature sensors can be integrated with the chip and/or can be external to the chip. A temperature measurement from an external temperature sensor can indicate an ambient temperature that corresponds to the boot-up temperature of the chip. Boot-up can be used when the chip is off (non-activated) or on standby. The warming circuitry is only a portion of the total number of circuits on the chip. After activation of the warming circuitry when needed, one or more temperature sensors, such as placed within (integrated with) the chip, are interrogated during the booting sequence to obtain an operating temperature of the chip and determine if the operating temperature satisfies the targeted temperature. The one or more temperatures sensors used after activation can be the same one or more integrated sensors used before activation to determine if the warming circuitry is needed; i.e., is the chip at the boot-up temperature. The boot-up temperature and the targeted temperature can have the same value.

Consider, for example, the automotive industry standard of a MOT of −40 degrees Celsius and using a targeted temperature of zero degrees Celsius. During the booting sequence, the warming circuitry of the chip, which is configured to operate at −40 degrees Celsius, is activated when the boot-up temperature of the chip is not at the targeted temperature of zero degrees. Once the warming circuitry is activated, current flowing through the warming circuitry is increased and an operating temperature of the chip is checked using, for example, one or more temperature sensors embedded in the chip. Once the operating temperature satisfies a targeted temperature of zero degrees Celsius, the booting sequence can then activate additional circuitry, or functional circuitry, on the chip that is configured to operate at the target temperature of zero degrees and the warming circuitry can be turned-off. As with the warming circuitry, the temperature sensors are also configured to operate at the MOT. The functional circuitry is configured to perform designated functions depending on the type of chip. For example, the chip can be part of an autonomous control system for an automobile that is designated to direct steering of the automobile.

Using the booting sequence and warming circuitry as disclosed herein, not all of the circuits of a chip have to function at the MOT. Instead, designated circuitry of the chip (e.g., the warming circuitry and the integrated temperature sensors) is designed to operate at the MOT and used to warm the chip to the targeted temperature. Design time for the chip, therefore, can be reduced since timing requirements at the MOT do not have to be met for all of the circuits of the chip. Additionally, the area of the chip can be reduced since buffers would not be needed to artificially increase delay times to ensure timing compatibility at the MOT between the additional circuits of the chip. Thus the disclosed features can advantageously reduce chip design time and chip area.

Additionally, the warming circuitry can be circuitry on the chip that is designated for a different function after boot-up. Thus, instead of using area of the chip for circuits that are limited to warming during boot-up, the warming circuitry can be advantageously used for warming during booting and for another function during operation. For example, the warming circuitry can be current sinking circuitry that is used for voltage overshoot reduction and/or balancing of power, such as when the chips are used in datacenters. In one example, the warming circuitry can be ISINK cells available from NVIDIA Corporation of Santa Clara, California, which are turned ON for longer durations to balance datacenter power profile when the current consumption goes down. An example of an ISINK cell that can be used for a warming circuit is illustrated in FIG. 3 and is disclosed in U.S. patent application Ser. No. 18/186,389, which is incorporated herein by reference in its entirety.

FIG. 1 illustrates a block diagram of an example of a circuit board 100 including a boot controller 110 constructed according to the principles of the disclosure. In addition to the boot controller, the circuit board 100 includes at least one chip, represented by chip 120. The circuit board 110 can be part of various computing systems, such as systems for machines, wherein the chip 120 performs a designated function for the machines. The machines can be, for example, vehicles or robots. The machines can be autonomous machines, such as autonomous vehicles. and the chip 120 can be configured to direct steering. The chip 120 can be a computer vision chip that is used by the autonomous machines. In addition to boot controller 110 and chip 120, circuit board 100 can include additional components not illustrated in FIG. 1 that are common components of circuit boards that are well known in the art.

Boot controller 110 is configured to initiate booting of chip 120 in response to a boot-up signal. As such, the boot controller 110 responds to the boot-up signal by running a boot loader from boot memory (not shown), which is typically a boot ROM. In addition to the functions typically performed by a boot controller, boot controller 110 also performs the additional functions disclosed herein, such as activating warming circuitry of the chip 120 during boot-up when needed. Accordingly, in addition to the interface 112, the boot controller 110 also includes a warming controller 114. Boot controller 110, or a portion thereof, such as the warming controller, can be located on chip 120.

Interface 112 is configured to transmit and receive (i.e., communicate) data, such as receiving the boot-up signal that initiates a booting sequence. The interface 112 can be, for example, a pin that is designated to receive the boot-up signal. The boot-up signal can be received from, for example, a power-on button or another circuit of a computing system that includes the circuit board 100. As noted above, circuit board 100 can include multiple chips. Each of the multiple chips can include warming circuitry as represented by warming circuitry 126 and can be similarly activated by boot controller 110 as described herein. Accordingly, the boot-up signal can be used to activate multiple chips of the circuit board 100 according to the booting sequence.

In addition to the typical functions of a booting sequence, the boot controller 110 also ensures the chip 120 can operate at MOT. The warming controller 114 is configured to activate warming circuitry located on chip 120 when needed based on the boot-up temperature of chip 120. For example, warming controller 114 determines a temperature of chip 120 at boot-up and activates warming circuitry of the chip during the booting sequence when the chip temperature is less than a boot-up temperature. Warming controller 114 can interact with temperature sensors located on or external to chip 120 to obtain temperature measurements. Temperature sensor 116 represents one or more temperature sensors that are external to chip 120 and temperature sensor 124 represents one or more temperature sensors integrated with chip 120. Temperature sensors 116 and 124 can be typical sensors that are used in the art to indicate a temperature and operate at the MOT. After activating warming circuitry 126, warming controller 114 can check the temperature of the chip again to determine if the targeted operating temperature of chip 120 has been obtained. If the chip temperature is at least the targeted temperature, warming controller 114 can deactivate warming circuitry 126. Boot controller 110 can activate additional circuits of chip 120, represented by functional circuitry 122 in FIG. 1, according to the booting sequence once the targeted temperature is obtained.

In addition to the temperature sensor 124 and the warming circuitry 126, chip 120 includes functional circuitry 122 that is configured to provide one or more functions. Circuit board 100, for example, can be part of a control system for an autonomous vehicle and the functional circuitry 122 can provide steering control. As noted above, depending on the implementation the functional circuitry 122 can also perform other operations, such as operations for computer vision systems. Circuit board 100 could also be located in a data center wherein chip 120 can be used for various functions including, for example, machine learning, artificial intelligence, data mining, etc.

Warming circuitry 126 is used to increase the temperature of chip 120 during the booting sequence. One or more of the warming circuits of the warming circuitry 126 can have a fixed current flow or variable current flow. As such, the warming circuitry 126 can be a combination of fixed and variable current flow warming circuits. The amount of current flowing through the warming circuitry 126, therefore, can be controllable. For example, different bias voltages can be selected to obtain a desired current flow. The warming circuitry 126 can use a current capacity controller, such as in FIGS. 2 and 3, to select the desired current amount. The desired amount of current can be based on various factors, such as, the amount of time available for warm-up, the number of current circuitries located on the chip, and a total amount of current needed for warm-up. A selection signal can be used to select the desired amount of current for operation during the booting sequence. The desired current amount and corresponding selection signal can be determined before booting of the chip 120, such as during manufacturing. The selection signal can be sent by the boot controller 110. More specifically, the selection signal can be sent by the warming controller 114. For fixed current flow, a selection signal is not needed, and an activation/deactivation signal is simply used. Warming circuits 200 and 300 of FIGS. 2-3 provide examples of variable current flow warming circuits having a current capacity controller.

FIG. 2 illustrates a block diagram of an example of a single variable flow warming circuit 200 constructed according to the principles of the disclosure. Warming circuit 200 includes a current capacity controller 210 and a current source 220. Warming circuit 200 is configured to turn-on and turn-off upon receipt of an activation and deactivation signal from a warming controller, such as warming controller 114 of FIG. 1. The current capacity controller 210 is configured to generate a bias signal in response to a selection signal to control the amount of warming current provided by the current source 220. The current capacity controller 210 can include a voltage ladder and a multiplexer to provide the bias signal. FIG. 3 provides an example of a current capacity controller having a voltage ladder with four resistors. A voltage ladder with more or less than four resistors can be used to provide different current options.

FIG. 3 illustrates a schematic diagram of an example of a single variable flow warming circuit 200 constructed according to the principles of the disclosure. The warming circuit 300 uses a configurable and selectable bias signal to control an amount of current between a power rail (VDD) and a ground plane or rail. A chip may have multiple instances of the warming circuit 200 located throughout (e.g., warming circuitry) that can be activated for warming during the boot-up process.

The warming circuit 200 includes a current capacity controller 310 and a current source 320. The current capacity controller 310 includes a voltage ladder 312 and a selector 314. The current capacity controller 310 allows selection of a current amount, a selectable current, via selection of a bias voltage with appropriate settings of the resistors on the voltage ladder 312. A selection signal controls the selector 314 to select the bias voltage. The selector can be a multiplexer. The current capacity controller 310 has 2ⁿ configurations (i.e., possible values of the bias signal selected from the voltage ladder 312 by the selector 314) where n is the bit width of the selection signal. For warming circuit 300, the various bias voltages that may be selected (e.g., where n=2) may be configured by way of the voltage ladder 312 resistor values to achieve 25%, 50%, 75% and 100% of the potential warming current throughput of a transistor 322 of the current source 320.

The warming circuit 200 is activated by an enable signal received from a warming controller, such as warming controller 114 of FIG. 1, during a booting sequence. The selection signal is also received during the booting sequence to control the current capacity. The enable signal and the selection signal can be received via various configuration pins (represented by CFG in FIG. 3) controlled during the booting sequence.

FIG. 4 illustrates a flow diagram of an example of a method 400 of booting a chip carried out according to the principles of the disclosure. Method 400 uses a booting sequence that allows booting a chip at a MOT when the chip includes some circuits that are not configured to operate at the MOT. As such, method 400 can be used in harsh environments when the MOT is for example, −40 degrees Celsius. Method 400 starts at step 405 with a chip that needs booting and continues to step 410 when a boot-up signal is received.

In step 420, a booting sequence for the chip is initiated in response to the receipt of the boot-up signal. One or more of the steps of method 400 can be performed or initiated by a boot controller, such as boot controller 110 of FIG. 1. The boot controller can be implemented as software, hardware, or a combination thereof. At least a portion of the booting sequence can correspond to one or more algorithms encoded as operating instructions on a non-transitory computer readable medium.

A temperature of the chip is checked during the booting sequence in step 430. The temperature can be sensed via one or more temperature sensors that are configured to operate at a temperature that is less than an operating temperature of the chip. The operating temperature of at least some of the one or more temperature sensors can be the MOT. The chip, therefore, can include one or more temperature sensors that are distributed throughout and are operable at the MOT. The location and number of temperature sensors can be determined during design of the chip and can vary based on the type of chip. For step 430, the one or more temperature sensors can include one or more temperature sensors that are configured to operate at a temperature that is greater than the MOT and/or lesser than the MOT.

In step 440, warming circuitry of the chip is activated during the booting sequence when the chip temperature is not at a first temperature. The first temperature is greater than the MOT and can be an operating temperature for the chip. For example, the operating temperature can be zero degrees Celsius for chips in the automobile industry. The warming circuity can include one or more warming circuits that are configured to operate at a second temperature that is less than the first temperature. The second temperature can be the MOT. The warming circuits can be activated via a warming controller, such as warming controller 114 of FIG. 1. When the chip temperature is at least at the first temperature, the warming circuitry is not needed, and the booting sequence can continue. For example, the booting sequence can activate functional circuitry of the chip such as in step 470.

When the warming circuitry is activated, a chip temperature is checked during the booting sequence in step 450. The chip temperature can be checked multiple times during the booting sequence. The number of times and the frequency of checking the chip temperature after activation of the warming circuitry can be predetermined during the design of the chip and can be based on factors of the booting sequence and the chip. For example, one factor can be the amount of time of the booting sequence. At least some of the temperature sensors used in step 430, such as those that have been configured to operate at the MOT or less, can be used to determine the chip temperature after activation of the warming circuitry.

In step 460, the warming circuitry is deactivated when the chip temperature is the first temperature. For example, once the chip temperature reaches the operating temperature of functional circuitry on the chip, the warming circuitry can be turned-off. The warming controller can send a deactivation signal to turn-off the warming circuits.

In step 470, one or more functional circuits of the chip are activated when the chip temperature is the first temperature. For example, when the operating temperature of the functional circuitry is reached as determined in step 460, the functional circuitry is activated via the booting sequence. At this point the functional circuitry can be activated as typically done during a booting sequence. The chip is now activated and method 400 continues to step 480 and ends.

FIG. 5 illustrates a flow diagram of an example of a method 500 of configuring a boot loader for a chip carried out according to the principles of the disclosure. Method 500 considers that the chip needs to satisfy operating at a MOT but includes circuitry that has not been validated to operate at the MOT. Accordingly, method 500 determines and uses a booting sequence that advantageously uses warming circuitry of the chip that is validated to operate at the MOT wherein other circuitry of the chip is not validated to operate at the MOT. Method 500 begins at step 505.

In step 510, an available amount of time for heating a chip from a first temperature to a second temperature during booting of the chip is determined. The available amount of time can be based on the time of a booting sequence for the chip. For example, the booting sequence can be designed to enable functional circuitry, and the available amount of time can be when the booting sequence is initiated to when the functional circuitry will be enabled according to the booting sequence.

A total amount of current required for heating the chip from the first temperature to the second temperature during the available amount of time is determined in step 520. The total amount of current can be determined based on simulation. A simulation program for integrated circuits can be used.

In step 530, the booting sequence is loaded in the boot loader, wherein the booting sequence includes instructions for activating warming circuitry of the chip to attain the total amount of current in the available amount of time. For example, the total number of warming circuits that the warming circuitry includes is known and the amount of current needed from each of the warming circuits to satisfy the total current amount can be determined by simple division for equal contribution. The warming circuitry can include a combination of different types of warming circuits, such as fixed or variable, and can also include warming circuits that have different current capacity. A combination of different amounts of current from different warming circuits and/or different combinations of activated warming circuits can also be used to achieve the total amount of current needed. When a warming circuit is variable, the instructions can provide configuration for a selection signal to select the appropriate current amount.

Method 500 continues to step 540 and ends. Once the booting sequence is loaded, the chip can be booted such as performed by method 400.

A circuitry of the above-described apparatus, systems or methods may be embodied in or performed by various digital data processors or computers, wherein the computers are programmed or store executable programs of sequences of software instructions to perform one or more of the steps of the methods. The software instructions of such programs may represent algorithms and be encoded in machine-executable form on non-transitory digital data storage media, e.g., magnetic or optical disks, random-access memory (RAM), magnetic hard disks, flash memories, and/or read-only memory (ROM), to enable various types of digital data processors or computers to perform one, multiple or all of the steps of one or more of the above-described methods, or functions, systems or apparatuses described herein.

The digital data processors or computers can be comprised of one or more GPUs, one or more CPUs, one or more of other processor types, or a combination thereof. The digital data processors and computers can be located proximate each other, proximate an intelligent machine such as an AV, in a cloud environment, a data center, or located in a combination thereof. For example, some components can be located proximate the intelligent machine, such as a trained neural motion planner, and some components can be located in a cloud environment or data center, such as a neural motion planner that is being trained.

The GPUs can be embodied on a single semiconductor substrate, included in a system with one or more other devices such as additional GPUs, a memory, and a CPU. The GPUs may be included on a graphics card that includes one or more memory devices and is configured to interface with a motherboard of a computer. The GPUs may be integrated GPUs (iGPUs) that are co-located with a CPU on a single chip.

The processors or computers can be part of GPU racks located in a data center. The GPU racks can be high-density (HD) GPU racks that include high performance GPU compute nodes and storage nodes. The high performance GPU compute nodes can be servers designed for general-purpose computing on graphics processing units (GPGPU) to accelerate deep learning applications. For example, the GPU compute nodes can be servers of the DGX product line from NVIDIA Corporation of Santa Clara, California.

The compute density provided by the HD GPU racks is advantageous for AI computing and GPU data centers directed to AI computing. The HD GPU racks can be used with reactive machines, autonomous machines, self-aware machines, and self-learning machines that all require a massive compute intensive server infrastructure. For example, the GPU data centers employing HD GPU racks can provide the storage and networking needed to support large-scale neural network (NN) training, such as for the NNs disclosed herein used for neural motion planners. The NNs can be Deep Neural Networks (DNN).

The NNs disclosed herein include multiple layers of connected nodes that can be trained with input data to solve complex problems. For example, contextual data, UPC, proposed trajectories, or a combination thereof can be used as input data for training of the NN. Once the NNs are trained, the NNs can be deployed and used to generate planned trajectories.

In one example of training, data flows through the NNs in a forward propagation phase until a prediction is produced that indicates a label corresponding to the input. When the NNs do not correctly label the input, errors between the correct label and the predicted label are analyzed, and the weights are adjusted for features of the layers during a backward propagation phase that correctly labels the inputs in a training dataset. With thousands of processing cores that are optimized for matrix math operations, GPUs such as noted above are capable of delivering the performance required for training NNs for artificial intelligence and machine learning applications.

Circuitries of disclosed embodiments may relate to computer storage products with a non-transitory computer-readable medium that have program code thereon for performing various computer-implemented operations that embody a part of an apparatus, device or carry out the steps of a method set forth herein. Non-transitory used herein refers to all computer-readable media except for transitory, propagating signals. Examples of non-transitory computer-readable media include, but are not limited to: magnetic media such as hard disks, floppy disks, and magnetic tape; optical media such as CD-ROM disks; magneto-optical media such as floptical disks; and hardware devices that are specially configured to store and execute program code, such as ROM and RAM devices. Configured or configured to as used herein means programmed, designed, and/or constructed with the necessary features and/or logic to perform a function or task. Examples of program code include both machine code, such as produced by a compiler, and files containing higher level code that may be executed by the computer using an interpreter.

In interpreting the disclosure, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

Those skilled in the art to which this application relates will appreciate that other and further additions, deletions, substitutions and modifications may be made to the described embodiments. It is also to be understood that the terminology used herein is for the purpose of describing particular embodiments only, and is not intended to be limiting, since the scope of the present disclosure will be limited only by the claims. Unless defined otherwise, all technical and scientific terms used herein have the same meaning as commonly understood by one of ordinary skill in the art to which this disclosure belongs. Although any methods and materials similar or equivalent to those described herein can also be used in the practice or testing of the present disclosure, a limited number of the exemplary methods and materials are described herein.

It is noted that as used herein and in the appended claims, the singular forms “a”, “an”, and “the” include plural referents unless the context clearly dictates otherwise.

Various aspects of the disclosure can be claimed including the systems and methods. Each of the independent claims provided below may have one or more of the elements of the dependent claims presented below in combination.

Those skilled in the art to which this application relates will appreciate that other and further additions, deletions, substitutions and modifications may be made to the described embodiments.

What is claimed is:

1. A method of booting a chip, comprising:
initiating a booting sequence for a chip in response to receiving a boot-up signal;
determining a chip temperature;
activating warming circuitry of the chip during the booting sequence when the chip temperature is less than a first temperature, wherein the warming circuity is configured to operate at a second temperature;
when activated, deactivating the warming circuitry when the chip temperature is equal to or greater than the first temperature; and
activating one or more additional circuits of the chip when the chip temperature is equal to or greater than the first temperature, wherein the first temperature is greater than the second temperature.

2. The method as recited in claim 1, wherein activating the warming circuitry includes setting a current for the warming circuitry using a biasing signal.

3. The method as recited in claim 1, wherein the warming circuity is configured for a different function after boot-up of the chip.

4. The method as recited in claim 1, wherein the warming circuity includes multiple individual warming circuits distributed on the chip.

5. The method as recited in claim 1, wherein the warming circuitry is current sinking circuitry.

6. The method as recited in claim 1, wherein the additional circuits are configured to operate at the first temperature.

7. The method as recited in claim 1, wherein the second temperature is a minimum operating standard of an industry.

8. The method as recited in claim 7, wherein the industry is an automotive industry.

9. The method as recited in claim 1, wherein the second temperature is −40.0 degrees Celsius.

10. A boot controller for initiating a booting sequence of a chip, comprising:
an interface for receiving a boot-up signal, wherein the boot-up signal initiates the booting sequence; and
a warming controller to perform operations during the booting sequence that include:
sensing a chip temperature using one or more temperature sensors,
activating warming circuitry of the chip when the chip temperature is less than a first temperature, wherein the warming circuity is configured to operate at a second temperature,
checking the chip temperature when the warming circuitry is activated, and
deactivating the warming circuitry after activation when the chip temperature is at least the first temperature.

11. The boot controller as recited in claim 10, wherein the warming circuity is configured for a different function during operation of the chip after boot-up of the chip.

12. The boot controller as recited in claim 10, wherein the warming circuity includes multiple individual circuits distributed on the chip.

13. The boot controller as recited in claim 12, wherein the multiple individual circuits include current sinking circuitry.

14. The boot controller as recited in claim 10, wherein activating the warming circuitry includes setting a current for the warming circuitry.

15. The boot controller as recited in claim 14, wherein setting the current includes selecting a biasing voltage for the warming circuitry.

16. The boot controller as recited in claim 10, wherein the booting sequence further includes activating one or more additional circuits of the chip when the chip temperature is at least the first temperature, wherein the first temperature is higher than the second temperature and the one or more additional circuits are configured to operate at the first temperature.

17. The boot controller as recited in claim 10, wherein the second temperature is a minimum operating temperature of an industry standard.

18. The boot controller as recited in claim 17, wherein the industry standard is an automotive industry standard.

19. The boot controller as recited in claim 18, wherein the chip is part of an autonomous operating system of a vehicle.

20. The boot controller as recited in claim 10, wherein the boot controller is implemented in a ROM communicatively coupled to the chip.

21. A method of configuring a boot loader for a chip, comprising:
determining an available amount of time for heating a chip from a first temperature to a second temperature during a booting sequence of the chip;
calculating a total amount of current required for heating the chip from the first temperature to the second temperature during the available amount of time; and
loading the booting sequence in the boot loader, wherein the booting sequence includes instructions for activating warming circuitry of the chip to attain the total amount of current in the available amount of time.

22. The method as recited in claim 21, wherein the booting sequence further includes instructions for determining a chip temperature and deactivating the warming circuitry when the chip temperature is at least the second temperature.

23. The method as recited in claim 21, wherein the booting sequence further includes instructions for activating additional circuits of the chip when the chip temperature is at least the second temperature.

24. The method as recited in claim 21, wherein the warming circuitry includes multiple warming circuits and the total current is satisfied by current provided by one or more of the multiple warming circuits.

25. The method as recited in claim 21, wherein the first temperature is a minimum operating temperature of a standard for the automotive industry and the second temperature is a targeted temperature that is higher than the minimum operating temperature.

26. The method as recited in claim 21, wherein the warming circuitry has a variable amount of current and the instructions include providing a selection signal for selecting the variable current amount that satisfies the total current.

27. A computer program product having a series of operating instructions stored on a non-transitory computer readable medium that direct operation of one or more processors when initiated to perform a booting sequence for a chip, the booting sequence comprising:
activating warming circuitry of a chip when a temperature of the chip is less than a first temperature, wherein the warming circuity is configured to operate at a second temperature;
sensing the chip temperature during the booting sequence when the warming circuitry is activated; and
deactivating the warming circuitry after the sensing when the chip temperature is equal to or greater than the first temperature.

28. The computer program product as recited in claim 27, wherein the booting sequence further includes activating one or more additional circuits of the chip when the chip temperature is the first temperature, wherein the first temperature is higher than the second temperature.

29. The computer program product as recited in claim 27, wherein the second temperature is an industry standard minimum operating temperature.

30. The computer program product as recited in claim 29, wherein the first temperature is zero degrees Celsius.
